(19) United States
(12) Patent Application Publication
(10) Pub. No.: US 2013/0106644 A1
(43) Pub. Date: May 2, 2013

(54) ULTRA LOW POWER HOMODYNE MOTION SENSOR

(71) Applicants: Peter Clifford Haugen, Livermore, CA (US); Gregory Ernest Dallum, Livermore, CA (US); Carlos Enrique Romero, Livermore, CA (US)

(72) Inventors: Peter Clifford Haugen, Livermore, CA (US); Gregory Ernest Dallum, Livermore, CA (US); Carlos Enrique Romero, Livermore, CA (US)

(73) Assignee: Lawrence Livermore National Security, LLC, Livemore, CA (US)

(21) Appl. No.: 13/287,902

(22) Filed: Nov. 2, 2011

(51) Int. Cl. G01S 13/56; H03K 3/03

(52) U.S. Cl. 342/28; 331/57

(57) ABSTRACT

Power consumption in an oscillator formed of a chain of two inverters in series, with resistive feedback from the output of the first inverter to its input, and capacitive feedback from the output of the second inverter to the input of the first inverter is lowered by reducing the supply voltage to the two inverters and reducing the voltage swing at the input to the first inverter. The supply voltage is reduced by adding one or more diodes, or other voltage reducing elements or means for reducing the voltage, between the power and ground rails of the power source and the power and ground inputs of the two inverters, and the voltage swing is reduced by selecting the feedback capacitor.

GOVERNMENT RIGHTS

The United States Government has rights in this invention pursuant to

Contract No. DE-AC52-07NA27344 between the U.S. Department of Energy and Lawrence Livermore National Security, LLC, for the operation of Lawrence Livermore National Laboratory.

### BACKGROUND OF THE INVENTION

1. Field of the Invention

This invention pertains generally to homodyne motion sensors, and more particularly to the transmitter in a homodyne motion sensor, and most particularly to the oscillator in the transmitter in a homodyne motion sensor and control of its power consumption.

2. Description of Related Art

Homodyne motion sensors send out two bursts of RF signals that are separated by a time corresponding to a pre-determined distance. If the first burst hits a moving object and the returned signal falls within the duration of the second burst, the mix of the two (returned signal and second burst) will add either constructively or destructively in time depending on the phase relationship of the two signals at that particular moment. The distance between the original and the delayed duplicate of the original RF pulse (the second burst) determines the range of detection.

The sensor transmits these two pulses at the pulse repetition frequency or rate controlled by the internal oscillator. After a series of analyses and measurements, it has been observed that the most power hungry portion of the entire sensor is the oscillator section in the transmitter. Previously, a two stage inverter chain has been used to implement the oscillator. The feedback resistor and capacitor values were chosen to bring the oscillation frequency to a desired value, but without consideration for the optimization of power consumption.

Homodyne motion sensors based on impulse or ultra-wideband (UWB) radar have been successfully integrated into various applications at Lawrence Livermore National Laboratory (LLNL). All these applications intend a stand-alone mobile operation using an internal battery included in the overall system for power, making power management an utmost important factor for the longest operation possible.

Accordingly it is desirable to reduce power consumption in a homodyne motion sensor. It is further desirable to reduce power consumption in a homodyne motion sensor by improving the design of the oscillator portion of the transmitter circuit, since that is the part of the sensor that consumes the most power.

### BRIEF SUMMARY OF THE INVENTION

An aspect of the invention is an oscillator having a chain of two inverters in series, with resistive feedback from the output of the first inverter to its input, and capacitive feedback from the output of the second inverter to the input of the first inverter; at least one voltage reducing element connected between at least one of the power and ground inputs of the first and second inverters and at least one of the power and ground rails of a power source; wherein the at least one voltage reducing element is selected to drop the voltage applied across the first and second inverters to a value slightly above their minimum specified operating voltage. The at least one voltage reducing element is preferably at least one diode. The oscillator of the invention may be followed by a level shifter, and may form part of a transmitter that may be part of a homodyne motion sensor along with a receiver.

Another aspect of the invention is a method for reducing power consumption in an oscillator formed of a chain of two inverters in series, with resistive feedback from the output of the first inverter to its input, and capacitive feedback from the output of the second inverter to the input of the first inverter, the method by reducing the supply voltage to the two inverters to a value slightly above their minimum specified operating voltage; and reducing the voltage swing at the input to the first inverter.

Further aspects of the invention will be brought out in the following portions of the specification, wherein the detailed description is for the purpose of fully disclosing preferred embodiments of the invention without placing limitations thereon.

### BRIEF DESCRIPTION OF THE DRAWINGS

The invention will be more fully understood by reference to the following drawings which are for illustrative purposes only:

FIG. 1 is a schematic diagram of an oscillator circuit of the invention.

FIG. 2 is an illustrative waveform at the input to the first inverter of an oscillator of the invention, showing the voltage swing with (solid line) and without (dashed line) capacitive feedback optimization.

FIG. 3 is a block diagram of an ultra-low power homodyne motion sensor of the invention.

### DETAILED DESCRIPTION OF THE INVENTION

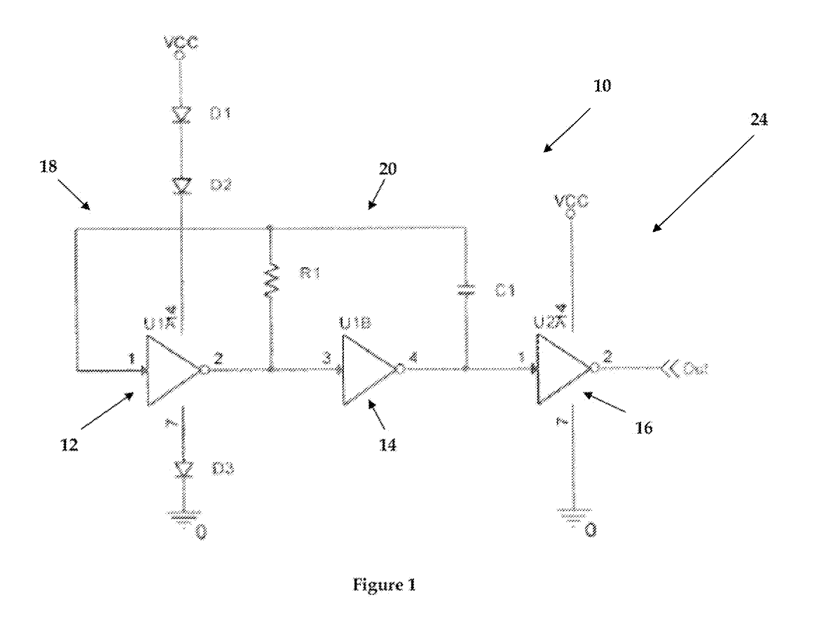

Referring more specifically to the drawings, for illustrative purposes the present invention is embodied in the apparatus and method generally shown in FIG. 1 through FIG. 3. It will be appreciated that the apparatus may vary as to configuration and as to details of the parts, and the method may vary as to its particular implementation and as to specific steps and sequence, without departing from the basic concepts as disclosed herein.

The invention applies to an ultra low power homodyne motion sensor or detector based on impulse or ultra-wideband radar. The invention greatly reduces power consumption of homodyne motion sensors by optimizing the oscillator portion of the transmitter circuit. The voltage swing through the oscillator is level shifted and minimized, resulting in a factor of twenty reduction in power consumption.

FIG. 1 shows an oscillator 10 of the invention that is formed of a chain of two inverters (U1A, U1B) 12, 14 in series. The two inverters 12, 14 define two stages of the oscillator 10. Oscillator 10 is followed by a level shifter 24 formed of a third inverter (U2A) 16. Level shifter 24 is not part of the oscillator 10. Level shifter 24 takes the lower drive level signals from oscillator 10 and converts them to the larger drive levels required by the rest of the circuitry. In one embodiment, the first and second inverters 12, 14 are on a first inverter chip U1, and the third inverter 16 is on a second inverter chip U2. Oscillator 10 and level shifter 24 are powered from power supply rails Vcc and GND where Vcc is the power supply voltage. However, while the power and ground inputs of inverter 16 of level shifter 24 is connected directly to Vcc and GND, e.g. pin 14 of chip U2 is connected to Vcc and pin 7 to GND, the power and ground inputs of inverters 12, 14 of oscillator 10 are connected to Vcc through series diodes D1, D2 and to GND through diode D3, e.g. pin 14 of chip U1 is connected to Vcc through series diodes D1, D2 and pin 7 to GND through D3. Thus the power supply rails for oscillator 10 may be considered to be the voltages directly across inverters 12, 14, which are less than Vcc to GND because of the voltage drops across the diodes.

In oscillator 10, feedback from after the first and second stages, i.e. from the outputs of inverters 12, 14 to the beginning of the chain, i.e. to the input of inverter 12, is provided. At the output of the first inverter 12 there is resistive feedback to the input of the first inverter 12. This resistive feedback is provided by connecting the output of inverter 12 through feedback resistor R1 in feedback loop 18 to the input of inverter 12. At the output of the second inverter 14 there is capacitive feedback to the input of the first inverter 12. This capacitive feedback is provided by connecting the output of inverter 14 through feedback capacitor C1 in feedback loop 20 to the input of inverter 12.

Depending on the state at the input and output of first inverter 12, current will flow through the feedback resistor R1 from high to low potential. Inverter 12 will reach an unstable state and eventually the input and output state will flip at a time determined by the value of the feedback resistor R1 and the total switching capacitance looking into the inverter 12.

The capacitive feedback after the second inverter 14 ensures that the first inverter 12 will be brought out of the unstable state by coupling the voltage change at the output of inverter 14 to the input of inverter 12. When the transmitter is turned on, the input of inverter 12 begins at the unstable state but due to the presence of noise, the state will eventually move to either high or low and begin the oscillation.

Static power consumption, compared to the dynamic power consumption, is miniscule because the inverter is constantly switching. Dynamic power is given by the formula:

P=V²·C·f+V_{avg}²/R

P is the power consumed, C is the switching capacitance in the circuit, f is the frequency of oscillation, V is the voltage swing, and R is the value of the feedback resistor R1. V is the voltage from the Vcc pin on the inverter chip to the GND pin on the inverter chip, i.e. the voltage across the inverter; this is not the power supply voltage Vcc because of the voltage drops across diodes D1, D2, D3. The switching capacitance C is the total capacitance inside the inverter package plus any additional external capacitances that are switched during the operation. The frequency f is a design variable. V_{avg} is the average voltage over the feedback resistor R1 and is related to V.

In terms of saving power, reducing the supply voltage and the voltage swing through the inverter chain will make the most dramatic impact since according to the dynamic power consumption formula, power is directly related to the square of V whereas the capacitance and the frequency relate linearly to power. Therefore, in this invention, the selected inverters are biased at the minimum specified operating voltage (they will work at lower voltage levels but their operation is not guaranteed) and the voltage swing is also reduced to the range set by the power supply rails.

The power supply rails are nominally just the power and ground lines Vcc and GND from the supply. In the oscillator of the invention, the power supply rails of the oscillator are the differences between the voltage measured on the Vcc pin of the chip and the GND pin on the chip. The added diodes D1, D2, D3 are reducing the applied voltage across the inverter chip. In an illustrative embodiment, the power supply voltage Vcc is 2.5 V. The diodes have been chosen such that each drops about 0.28 V at the operating current levels. The voltage that is across the chip is then 1.66 V. The minimum guaranteed voltage that this particular chip can operate on is 1.65 V.

While the invention is illustrated with an embodiment that includes three diodes D1, D2, D3 to drop the voltage applied across the inverters 12, 14 from the full power supply voltage to just above the minimum specified operating voltage, in general one or more diodes can be used, depending on the voltage drop of each diode and the total voltage drop required. Alternately one or more other voltage reducing elements may be used in place of the one or more diodes. In general, a means for reducing the voltage may be used.

Thus adding the diodes D1, D2, D3 to the power supply pins of inverters 12, 14 provides a means for reducing the power supply voltage to oscillator 10. This is done because Vcc from the power supply is greater than needed to operate the oscillator so the diodes are used to drop the voltage. Vcc cannot be lowered because the power supply voltage needed for other parts of the circuit, e.g. level shifter (driver) 24, are higher than that needed for the oscillator section.

While any other way of decreasing the voltage across the oscillator inverters can be used, using diodes has the benefit of being able to provide voltage reduction as well as level shifting of the oscillator's output signal. This level shifting optimizes the drive signal into the third inverter 16 (of level shifter 24) which is powered by the full supply voltage Vcc. The switching voltage at the input of an inverter is slightly less than half of the voltage applied across the device. By using the diodes as shown, one is level shifting the reduced output levels from the oscillator so they are closely centered around the switching levels of the driver stage (level shifter 24).

The output voltage levels of the inverter chips are digital and are at a level that is close to either the power supply voltage rail (the Vcc pin on the chip) or the ground rail (the level of the GND pin on the chip). Further, for low power operation, as is desired, the inverter chips must be CMOS based. The CMOS inverters have close to zero static current draw from the power supply.

Diodes are used to drop the positive supply voltage and increase the ground reference to a finite voltage in the oscillator section. As shown in FIG. 1, first inverter 12 (and second inverter 14 since it is part of the same chip package U1) is connected to supply voltage Vcc through a series pair of diodes D1, D2, and is connected to ground through diode D3. This allows DC level shifting, which allows the swing centered about the switching threshold of the inverter 16 in the next stage of the transmitter. Inverter 16 forms a driver stage of the transmitter of the motion sensor. Driver 24 is not a part of the oscillator. The reduced voltage oscillator 10 interfaces into and drives the power stage (driver 24) that is running on a higher voltage power supply (the full Vcc). The driver stage 24 needs to run at the higher power supply voltage in order to adequately drive the transmitter. However, since the input switching threshold of an inverter is slightly less than half of the power supply voltage applied to the chip, by reducing the voltage of the oscillator inverters, the power draw of the oscillator is reduced.

The input capacitance of the inverter is inherent and unchangeable. However, the feedback capacitance can be controlled and the optimal value can be picked. This value can be optimized by knowing the input capacitance and the switching threshold of the inverter gate. In an illustrative example, the published input capacitance of the inverter gate is 2.5 pF. The switching threshold can be determined by placing a capacitor that is about half the value of the input capacitance in the C1 location. C1 and the gate input capacitance form a capacitive voltage divider when driven by inverter 14. The voltage supplied by the output of inverter 12 is either Vcc or GND. By monitoring the duty cycle of the resulting oscillator, the switching threshold can be determined. In an ideal case, if the “HIGH” time at the oscillator output is equal to the “LOW” time (50% duty cycle), the input is switching at the middle of the applied power supply voltage.

If C1 and R1 are known, the input capacitance can be determined from the resultant frequency. C1 is in parallel with the input capacitance as far as the charging/discharging through R1 is concerned. Once this input capacitance value has been determined, C1 should be chosen to be the same value or slightly smaller. How much smaller is determined by the ratio of the actual switching threshold relative to the ideal center switching value.

At the input of a typical inverter, two clamping diodes to both supply rails exist. They are not the voltage reducing diodes D1, D2, D3 of the invention. These clamping diodes are part of the input protection circuitry that is built into the inverter chip. They primarily provide static electricity protection for the chip. They conduct when an input signal is a diode drop higher than the Vcc pin or a diode drop lower than the GND pin.

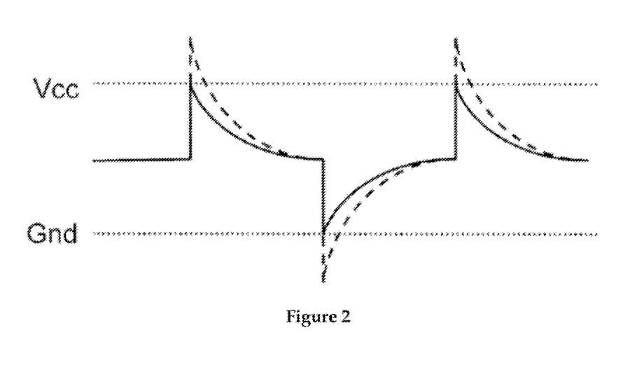

FIG. 2 shows an illustrative waveform at the input of the first inverter 12 of the oscillator 10 shown in FIG. 1. The solid waveform is the voltage swing with optimized capacitive feedback as described above and below, and swings between the supply rails Vcc and Gnd. The dotted waveform is the voltage swing without optimized capacitive feedback and ranges from greater than Vcc to below Gnd. Since the signal is essentially AC coupled by C1 into the input of inverter 12, if C1 is larger than the input capacitance of the inverter, then the signal will go negative. As shown in FIG. 2, any voltage swing in excess of the supply rails will be clamped by the clamping diodes, wasting energy in the process. Energy is dumped quickly into the ground and power supply when the input clamping diodes are forward biased. This energy is lost as heat and does not contribute to the oscillator function. This will require the use of larger values of C and lower values of R to provide the same oscillating frequency. These larger C and lower R values increase the power consumption of the oscillator. Therefore, limiting the voltage swing to the supply rails will reduce the power consumption of the oscillator as desired. By optimizing the drive signals such that the clamp diodes are never forward biased, current required from the power source will be minimized, and therefore power will be minimized for the same oscillating frequency. In order to limit the voltage swing within the range where the clamping diodes will remain reverse biased, the feedback capacitor has to be the same value as the input capacitor. In a CMOS gate, the input is strictly a capacitive load until the input voltage range is exceeded. This is the input capacitor that is being described. This capacitance value is nominally provided in the data sheet for a particular chip, but may also be experimentally derived. The two capacitors form a voltage divider that cuts the voltage swing at the output of the second inverter in half, which adds up to the input swing at the input to the first inverter. The resulting waveform should peak to approximately equal the limiting values.

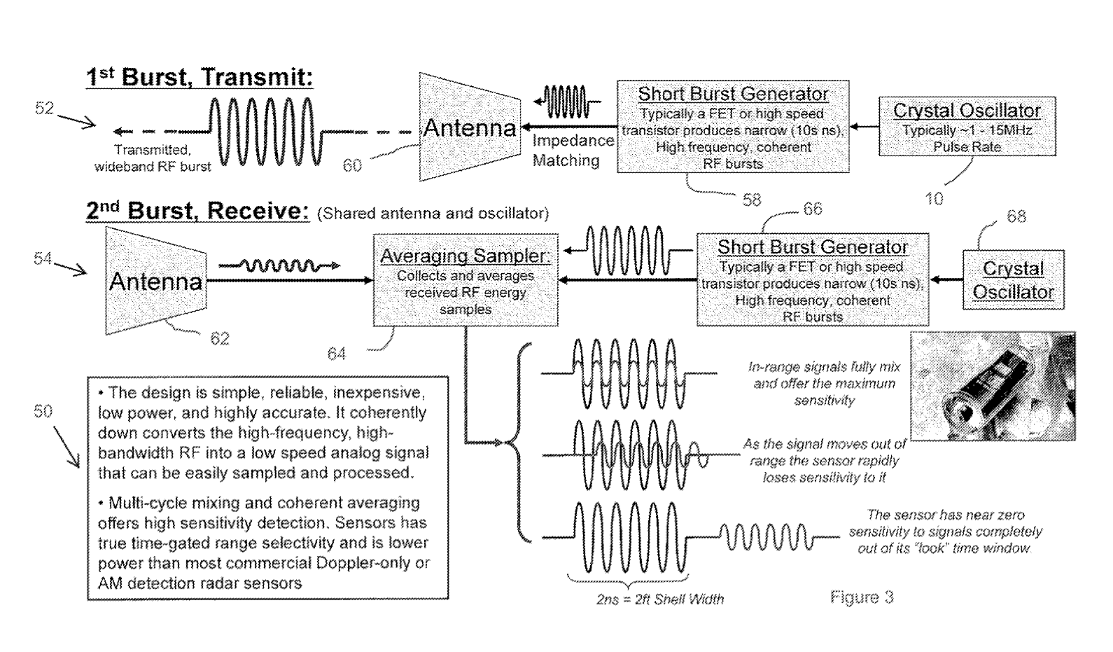

FIG. 3 shows an ultra low power homodyne motion sensor 50 of the invention, having an ultra low power transmitter 52 of the invention, including an ultra low power oscillator 10 of the invention (as shown in FIG. 1). Homodyne motion sensor 50 also includes a receiver 54. Transmitter 52 and receiver 54 may be integrated into a single unit called a transceiver or may be two separate units.

Transmitter 52 of homodyne motion sensor 50 includes oscillator 10, as described above, which has two stages formed of a chain of two inverters in series, with resistive feedback from the output of the first inverter to its input, and capacitive feedback from the output of the second inverter to the input of the first inverter. The supply voltage to the first two inverters is reduced by the addition of the diodes and the voltage swing is reduced by selecting the feedback capacitor, resulting in low power consumption.

In transmitter 52, oscillator 10 provides input pulses to a short burst generator 58. The level shifter/driver formed of the third inverter in FIG. 3 is not shown but may be included as part (an input stage) of the short burst generator 58, or may be included as a part (output stage) of oscillator 10, or may be a separate element between oscillator 10 and short burst generator 58. Oscillator 10 typically operates at a pulse repetition rate of 100 KHz to 10 MHz. Short burst generator 58 is typically a FET or SRD, and produces narrow (e.g. several to 10's of ns) high frequency coherent RF bursts. Generally, a pair of bursts, separated in time corresponding to a certain range, are produced on each cycle of oscillator 10. Short burst generator 58 is connected to antenna 60, typically with impedance matching, to transmit these wideband RF bursts.

When the RF bursts transmitted from antenna 60 hit a moving target, reflected pulses are received by antenna 62 of receiver 54. Antenna 62 is connected to averaging sampler 64 of receiver 54. Averaging sampler 64 also receives RF bursts from short burst generator 66 that is driven by oscillator 68. Short burst generator 66 and oscillator 68 are similar to short burst generator 58 and oscillator 10, and produce a similar sequence of RF bursts that are synchronized with those produced by short burst generator 58. When the moving target is at the selected range, the reflection from the first burst of each cycle will coincide with the second burst at the averaging sampler 64, producing an output signal indicating detection of a moving target at the selected range. While a sensor embodiment has been shown with separate transmitter and receiver with separate components, alternate embodiments with shared components may be used. For example, a single antenna may be used to both transmit and receive, e.g. antenna 60 may be connected to averaging sampler 64 so that received signals are input thereto, and a single oscillator and short burst generator may be used to produce the RF bursts, e.g. the output of short burst generator 58 may also be input into averaging sampler 64. In addition, short burst generators 58, 66 may produce just one RF burst per cycle if the output of short pulse generator 66 is delayed by a time corresponding to the desired range. If only a single short pulse generator 58 is used, its output can be connected to averaging sampler 64 through a delay of suitable length.

The invention also includes a method for reducing power consumption in an oscillator formed of a chain of two inverters in series, with resistive feedback from the output of the first inverter to its input, and capacitive feedback from the output of the second inverter to the input of the first inverter. Power consumption is lowered by reducing the supply voltage to the two inverters and reducing the voltage swing at the input to the first inverter. The supply voltage is reduced by adding one or more diodes, or other voltage reducing elements or means for reducing the voltage, between the power supply and ground rails and the two inverters, and the voltage swing is reduced by selecting the feedback capacitor.

The invention thus provides an impulse or ultra-wideband (UWB) radar homodyne motion sensor with ultra low power consumption. The ultra low power consumption allows the longest possible operation of stand-alone mobile sensors using internal batteries for power. Homodyne motion sensors have been successfully integrated into various applications such as Guard Dog Intrusion Sensors, Human Triggered Switches, and the Secure Box Sensors at Lawrence Livermore National Laboratory. Its ease of integration comes from the miniature size of the substrate and off-the-shelf components. The present invention provides homodyne motion sensors with ultra low power consumption for these and other applications. By level shifting and minimizing the voltage swing through the oscillator, the invention produces a factor of twenty reduction in power consumption compared to the prior art motion sensor without the invention.

Although the description above contains many details, these should not be construed as limiting the scope of the invention but as merely providing illustrations of some of the presently preferred embodiments of this invention. Therefore, it will be appreciated that the scope of the present invention fully encompasses other embodiments which may become obvious to those skilled in the art, and that the scope of the present invention is accordingly to be limited by nothing other than the appended claims, in which reference to an element in the singular is not intended to mean “one and only one” unless explicitly so stated, but rather “one or more.” All structural and functional equivalents to the elements of the above-described preferred embodiment that are known to those of ordinary skill in the art are expressly incorporated herein by reference and are intended to be encompassed by the present claims. Moreover, it is not necessary for a device to address each and every problem sought to be solved by the present invention, for it to be encompassed by the present claims. Furthermore, no element or component in the present disclosure is intended to be dedicated to the public regardless of whether the element or component is explicitly recited in the claims. No claim element herein is to be construed under the provisions of 35 U.S.C. 112, sixth paragraph, unless the element is expressly recited using the phrase “means for.”

What is claimed is:

1. An oscillator, comprising:
a chain of two inverters in series, with resistive feedback from the output of the first inverter to its input, and capacitive feedback from the output of the second inverter to the input of the first inverter; and
at least one voltage reducing element connected between at least one of the power and ground inputs of the first and second inverters and at least one of the power and ground rails of a power source;
wherein the at least one voltage reducing element is selected to drop the voltage applied across the first and second inverters to a value slightly above their minimum specified operating voltage.

2. The oscillator of claim 1, wherein the first and second inverters are CMOS inverters.

3. The oscillator of claim 1, wherein the at least one voltage reducing element is at least one diode.

4. The oscillator of claim 2, wherein the at least one voltage reducing element is at least one diode.

5. The oscillator of claim 1, wherein the capacitive feedback comprises a feedback capacitor whose capacitance is selected to minimize voltage swing at the input of the first inverter.

6. The oscillator of claim 5, wherein the at least one voltage reducing element is at least one diode.

7. The oscillator of claim 6, wherein the first and second inverters are CMOS inverters.

8. An apparatus, comprising:
an oscillator of claim 1; and
a level shifter connected to the oscillator output and powered directly by the power and ground rails of the power source.

9. The apparatus of claim 8, wherein the level shifter comprises a third inverter having its power and ground inputs connected directly to the power and ground rails of the power source.

10. A transmitter for a homodyne motion sensor, comprising:
an oscillator of claim 1;
a short burst generator driven by the oscillator and powered directly by the power and ground rails of the power source; and
an antenna connected to the short burst generator.

11. The transmitter of claim 10, wherein the first and second inverters are CMOS inverters and the at least one voltage reducing element is at least one diode.

12. The transmitter of claim 10, wherein the capacitive feedback comprises a feedback capacitor whose capacitance is selected to minimize voltage swing at the input of the first inverter.

13. The transmitter of claim 10, further comprising a level shifter connected to between the oscillator output and the short burst generator input, and powered directly by the power and ground rails of the power source.

14. A homodyne motion sensor, comprising:
a transmitter of claim 10 for transmitting a pair of RF bursts, separated in time corresponding to a certain range, on each cycle of oscillator; and
a receiver for receiving reflections of the RF bursts transmitted by the transmitter.

15. The motion sensor of claim 14, wherein the wherein the first and second inverters are CMOS inverters and the at least one voltage reducing element is at least one diode.

16. The motion sensor of claim 14, wherein the capacitive feedback comprises a feedback capacitor whose capacitance is selected to minimize voltage swing at the input of the first inverter.

17. The motion sensor of claim 14, wherein the receiver comprises:
a receive antenna;
an averaging sampler connected to the receive antenna;
a second oscillator; and
a second short burst generator connected between the second oscillator and the averaging sampler.

18. A method for reducing power consumption in an oscillator formed of a chain of two inverters in series, with resistive feedback from the output of the first inverter to its input, and capacitive feedback from the output of the second inverter to the input of the first inverter, the method comprising:
reducing the supply voltage to the two inverters to a value slightly above their minimum specified operating voltage; and
reducing the voltage swing at the input to the first inverter.

19. The method of claim 18, wherein reducing the supply voltage to the two inverters comprises connecting at least one voltage reducing element between at least one of the power and ground inputs of the first and second inverters and at least one of the power and ground rails of a power source, and
wherein the at least one voltage reducing element is selected to drop the voltage applied across the first and second inverters to a value slightly above their minimum specified operating voltage.

20. The method of claim 19, wherein the at least one voltage reducing element is at least one diode.
